(19) United States
(12) Patent Application Publication
(10) Pub. No.: US 2015/0041183 A1
(43) Pub. Date: Feb. 12, 2015

(54) CHIP BOARD PACKAGE STRUCTURE

(71) Applicant: KINSUS INTERCONNECT TECHNOLOGY CORP., Taoyuan (TW)

(72) Inventors: Jun-Chung Hsu, Taoyuan County (TW); Yu-Hui Wu, Kaohsiung City (TW); Huei-Cheng Hong, New Taipei City (TW)

(73) Assignee: KINSUS INTERCONNECT TECHNOLOGY CORP., Taoyuan (TW)

(21) Appl. No.: 13/960,082

(22) Filed: Aug. 6, 2013

(51) Int. Cl. H05K 1/11; H05K 1/02

(52) U.S. Cl. CPC H05K 1/113; H05K 1/0298
USPC 174/251; 174/263

(57) ABSTRACT

A chip board package structure includes a circuit board part, a chip board part and a solder used to solder the circuit board part and the chip board part. A chip on the chip board part is connected to an electrical circuit by wiring or soldering. A surface treatment metal layer includes at least nickel, palladium and gold formed on part of the surface of the circuit layer on the chip board. A copper-tin intermetallic compound is formed on joints of the second solder and the surface treatment metal layer, and the other part of the circuit layer is directly connected to the solder to form the copper-tin intermetallic compound. In addition to the lower package cost, with the shape feature of the copper-tin intermetallic compound, it is possible to increase the contact area with the solder, thereby improving the reliability of the soldering process and the yield.

### BACKGROUND OF THE INVENTION

1. Field of the Invention

The present invention generally relates to a chip board package structure, and more specifically to a chip board package structure which employs a copper-tin intermetallic compound, the surface treatment of nickel, palladium and gold, and the soldering process with copper-tin on the same package board to improve the reliability of soldering besides the lower package cost.

2. The Prior Arts

Owing to easy oxidation of copper when exposed to the external environment, to inhibit the oxidation when the chip board is being packaged, it is common to perform the process of gold electroplating on the surface of a circuit pattern not covered by the solder mask, such as the surface of the gold fingers or the connection pads. Gold has excellent property in electrical and thermal conductivities. However, the price of gold has been increasing such that the cost of manufacture kept surging. Although many surface treatments have been developed to replace the process of gold electroplating, some problems still exist. For example, the resulting electroplating layer has poor property in electrical and thermal conductivities, and peels off easily. Additionally, the thickness of the electroplating layer is too thick.

Therefore, it needs a chip board package structure which operates at lower cost and maintains or enhances the package structure with electroplating effect, thereby overcoming the drawbacks in the prior arts.

### SUMMARY OF THE INVENTION

The primary objective of the present invention is to provide a chip board package structure, which includes a circuit board part, a chip board part and a solder used to solder the circuit board part and the chip board part. The circuit board part includes a circuit substrate and a first circuit layer. The first circuit layer is provided on an upper surface of the circuit substrate, and includes a plurality of first circuit patterns and a plurality of first connection pads, which are connected to each other. The chip board part includes a chip board, a second circuit layer, a third circuit layer and a chip. The second circuit layer is formed on an upper surface of the chip board, and includes a plurality of second circuit patterns, a plurality of wiring pads and a chip base, which are connected to each other. A surface treatment metal layer is formed on upper surfaces of the second circuit patterns, the wiring pads and the chip base. Each of the surface treatment metal layer and the electrical conductive wires includes at least nickel, palladium and gold.

The chip is attached to the surface treatment metal layer on the chip base through a thermally conductive adhesive. A plurality of electrically conductive wires are connected to the respective wiring pads so as to electrically connect the chip and the second circuit layer. The third circuit layer is formed beneath a lower surface of the chip board and includes a plurality of third circuit patterns and a plurality of third connection pads, which are connected to each other. The second circuit layer and the third circuit layer are electrically connected to each other through at least one connection plug in one hole formed on the chip board.

Another objective of the present invention is to provide a chip board package structure, which includes a circuit board part, a chip board part and a first solder used to solder the circuit board part and the chip board part. The relation of the connection among the circuit board part, the chip board part and the first solder is similar to the above-mentioned. The chip board includes at least a second circuit layer, a third circuit layer and a first chip. The second circuit layer is formed on an upper surface of the chip board, and includes a plurality of second circuit patterns and a plurality of second connection pads, which are connected to each other. A surface treatment metal layer is formed on upper surfaces of the second circuit patterns and the second connection pads. Each of chip pins of the first chip is soldered to the corresponding second connection pad through a second solder. The third circuit layer is formed on the lower surface of the chip board and includes a plurality of third circuit patterns and a plurality of third connection pads, which are connected to each other. The second circuit layer and the third circuit layer are electrically connected to each other through at least one connection plug in one hole formed on the chip board.

The surface treatment metal layer includes at least nickel, palladium and gold. The joints of the second solder and the surface treatment metal layer on the second connection pads form the copper-tin intermetallic compound. Another copper-tin intermetallic compound is formed on the area where the first solder is in contact with the first, second and third connection pads. With the ordinary needle shape, the copper-tin intermetallic compound forms projections, which effectively increase the contact area with the solder, thereby improving the stability and reliability.

On part of the surface, the surface treatment metal layer including nickel, palladium and gold replaces the traditional electroplated gold, and on other part of the surface, copper-tin is directly soldered to form the copper-tin intermetallic compound and increase the contact area with the solder such that the reliability of soldering is improved and the cost of manufacturing is decreased. It is possible to greatly enhance its competitiveness in the market.

### BRIEF DESCRIPTION OF THE DRAWINGS

The present invention can be understood in more detail by reading the subsequent detailed description in conjunction with the examples and references made to the accompanying drawings, wherein:

FIG. 1 is a cross sectional view showing a chip board package structure according to a first embodiment of the present invention;

FIG. 2 is a cross sectional view showing a chip board package structure according to a second embodiment of the present invention;

FIG. 3 is a cross sectional view showing a chip board package structure according to a third embodiment of the present invention; and

FIG. 4 is a cross sectional view showing a chip board package structure according to a fourth embodiment of the present invention.

### DETAILED DESCRIPTION OF THE PREFERRED EMBODIMENTS

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

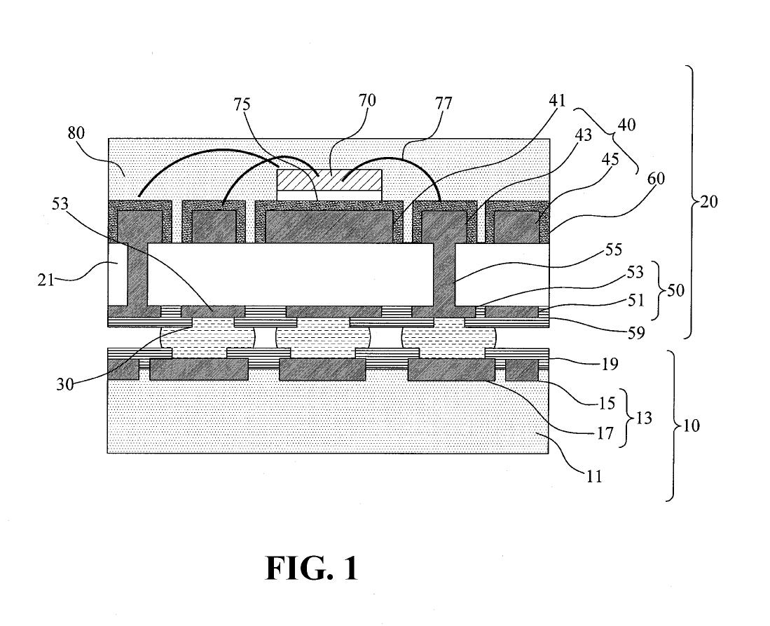

FIG. 1 shows a cross-sectional view of the chip board package structure according to the first embodiment of the present invention. As shown in FIG. 1, the chip board package structure of the present embodiment includes the circuit board part 10, the chip board part 20 and the first solder 30 used to solder the circuit board part 10 and the chip board part 20. The circuit board part 10 includes a circuit substrate 11 and a first circuit layer 13 provided on the upper surface of the circuit substrate 11. The first circuit layer 13 includes a plurality of first circuit patterns 15 and a plurality of first connection pads 17, which are connected to each other (not shown). Additionally, the upper surface of the circuit substrate 11 is further provided with the first solder mask 19 covering the first circuit patterns 15 and part of the first connection pads 17.

The chip board part 20 includes the chip board 21, the second circuit layer 40, the third circuit layer 50, the first chip 70 and the encapsulating glue 80. The second circuit layer 40 is formed on the upper surface of the chip board 21, and includes a plurality of second circuit patterns 41, a plurality of wiring pads 43 and the chip base 45, which are connected to each other (not shown). The upper surfaces of the second circuit patterns 41, the wiring pads 43 and the chip base 45 are provided with the surface treatment metal layer 60. The third circuit layer 50 is formed beneath the lower surface of the chip board 21 and includes a plurality of third circuit patterns 51 and a plurality of third connection pads 53, which are connected to each other (not shown). Moreover, the lower surface of the chip board 21 is provided with the third solder mask 59 covering the third circuit patterns 51 and part of the third connection pads 53. The second circuit layer 40 and the third circuit layer 50 are electrically connected to each other through at least one connection plug 55 in one hole (not shown) formed on the chip board 21.

The first chip 70 is attached to the surface treatment metal layer 60 on the chip base 45 through the thermally conductive adhesive 75. Further, electrically conductive wires 77 are connected to the respective wiring pads 43 so as to electrically connect the first chip 70 and the second circuit layer 40. The encapsulating glue 80 is formed on the upper surface of the chip board 21, and the second circuit layer 40, the surface treatment metal layer 60, the first chip 70, the thermally conductive adhesive 75 and the electrical wires 77 are covered encapsulating glue 80. The first solder 30 is formed between the upper surface of the circuit substrate 11 and the lower surface of the chip board 21 so as to solder the first connection pads 17 exposed from the first solder mask 19 and the corresponding third connection pads 53 exposed from the third solder mask 59. As a result, the circuit board part 10 and the chip board part 20 are electrically connected relative to each other.

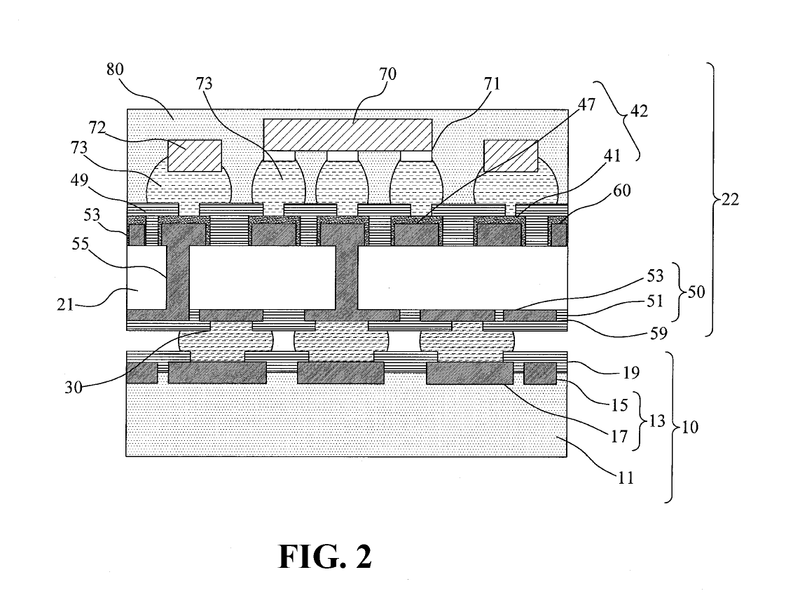

FIG. 2 shows a cross-sectional view of the chip board package structure according to the second embodiment of the present invention. As shown in FIG. 2, the chip board package structure of the second embodiment generally includes the circuit board part 10 and the chip board part 22, which are soldered and connected to each other by the first solder 30. The circuit board part 10 and the third circuit layer 50 of the chip board part 22, and the connection relation of the first solder 30 and the circuit board part 10 are the same as the first embodiment, and the detailed description is thus omitted.

The chip board part 22 includes the chip board 21, the second circuit layer 42, the third circuit layer 50, the first chip 70, at least one passive element 72 and the encapsulating glue 80. The second circuit layer 42 is formed on the upper surface of the chip board 21, and includes a plurality of second circuit patterns 41 and a plurality of second connection pads 47, which are connected to each other (not shown). The surface treatment metal layer 60 is formed on the upper surfaces of the second circuit patterns 41 and the second connection pads 47. The second solder mask 49 is provided on the upper surface of the chip board 21 and covers the second circuit patterns 41 and part of the second connection pads 47 so as to expose the second connection pads 47 provided on the surface treatment metal layer 60.

The chip pins 71 of the first chip 70 and the passive element 72 are soldered to the corresponding second connection pads 47 through the second solder 73, which is connected to the surface treatment metal layer 60. The second circuit layer 42 and the third circuit layer 50 are electrically connected to each other through at least one connection plug 55 in one hole (not shown) formed on the chip board 21. The encapsulating glue 80 is formed on the upper surface of the chip board 21, and covers the second circuit layer 42, the surface treatment metal layer 60, the first chip 70, the chip pins 71, the passive element 72 and the second solder 73. Similar to the first embodiment, the detailed description of the second embodiment is thus omitted.

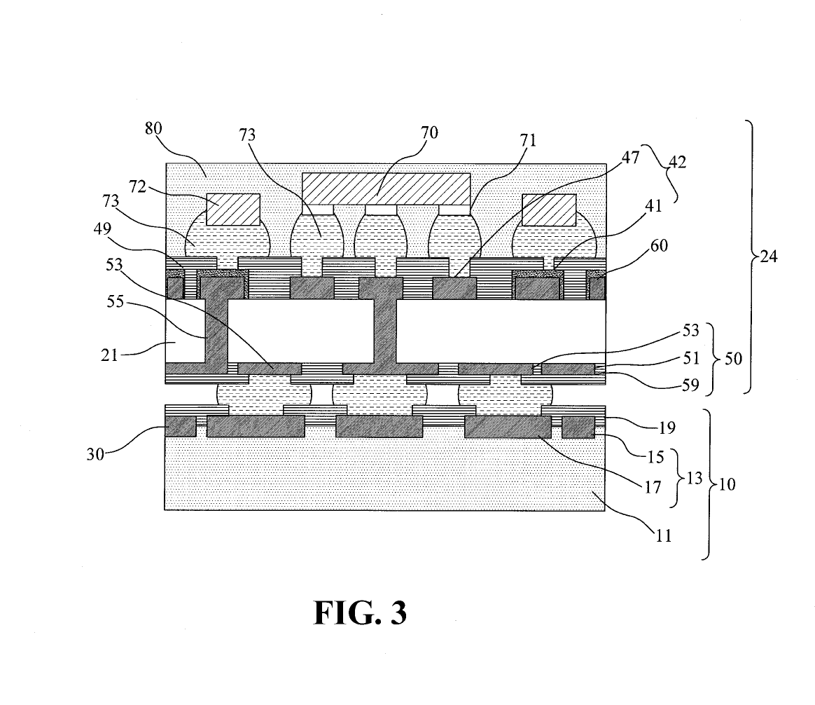

FIG. 3 shows a cross-sectional view of the chip board package structure according to the third embodiment of the present invention. As shown in FIG. 3, the chip board package structure of the third embodiment is modified from the second embodiment. Generally, the third embodiment is similar to the second embodiment. Only one difference is that the chip board part 24 of the third embodiment is a little different from the chip board part 22 of the second embodiment. Specifically, the second connection pads 47 soldered to the chip pins 71 of the first chip 70 are not provided with the surface treatment metal layer 60 such that the second connection pads 47 is directly in contact with the second solder 73. However, the second connection pads 47 soldered to the passive element 72 are provided with the surface treatment metal layer 60.

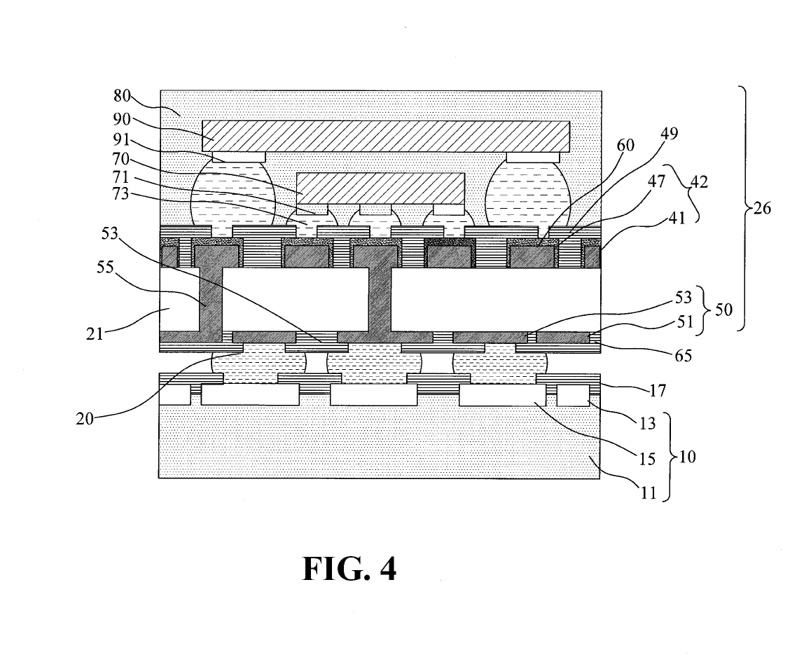

Furthermore, the chip board package structure according to the fourth embodiment of the present invention is shown in FIG. 4. The chip board package structure of the fourth embodiment is modified from the second embodiment. More specifically, the chip board package structure of the present embodiment includes the circuit board part 10 and the chip board part 26, which are electrically connected to each other by the first solder 30. The circuit board part 10 and the third circuit layer 50 of the chip board part 26, and the connection relation of the first solder 30 and the circuit board part 10 are the same as the second embodiment, and the detailed description is thus omitted.

The chip board part 26 includes the chip board 21, the second circuit layer 42, the third circuit layer 50, the first chip 70, the second chip 90 and the encapsulating glue 80. The second circuit layer 42 is formed on the upper surface of the chip board 21, and includes a plurality of second circuit patterns 41, a plurality of second connection pads 47, which are connected to each other (not shown). The upper surfaces of the second circuit patterns 41 and the second connection pads 47 are provided with the surface treatment metal layer 60. The second solder mask 49 is provided on the upper surface of the chip board 21, and covers the second circuit patterns 41 and part of the second connection pads 47. As a result, the second connection pads 47 on the surface treatment metal layer 60 are exposed.

The first chip 70 has a length smaller than the second chip 90. The first chip 70 is provided under the second chip 90. The chip pins 91 of the second chip 90 are provided on the outer rim and not in contact with the first chip 70. The chip pins 71 of the first chip 70 and the chip pins 91 of the second chip 90 are soldered to the corresponding second connection pads 47 through the second solder 73, which is connected to the surface treatment metal layer 60. The second circuit layer 42 and the third circuit layer 50 are electrically connected to each other through at least one connection plug 55 in one hole (not shown) formed on the chip board 21. The encapsulating glue 80 is formed on the upper surface of the chip board 21, and covers the second circuit layer 42, the surface treatment metal layer 60, the first chip 70, the second chip 90 and the second solder 73.

More specifically, the first circuit layer 13, the second circuit layer 40 and the third circuit layer 50 are made from copper. Each of the first solder 30 and the second solder 73 includes tin. Each of the surface treatment metal layer 60 and the conductive wires 77 contains nickel, palladium and gold. Therefore, the joints of the surface treatment metal layer 60 and the second solder 73 form the copper-tin intermetallic compound. For example, the copper-tin intermetallic compound includes at least Ni₆Sn₅, Ni₃Sn₄, (CuₓNi_{6-x-y}Pd_{y})Sn₅, (CuₓNi_{3-x-y}Pd_{y})Sn₄. The copper-tin intermetallic compound is generally of the needled-shape so as to increase the contact area with the solder. The cost is thus decreased and the reliability is effectively improved. At the same time, the contact areas of the first circuit layer 13, the second circuit layer 40 and the third circuit layer 50 with the first solder 30 or the second solder 73 may also form the copper-tin intermetallic compound, like Cu₆Sn₅, Cu₃Sn. The surfaces are formed with the projections at least such that the contact area is increased and the reliability of soldering is greatly improved.

One feature of the present invention is during the process of packaging the chip board, the traditional electroplated gold is replaced by the surface treatment metal layer on part of the surfaces, and copper and tin are directly soldered on other part of the surfaces such that the shape feature of the copper-tin intermetallic compound increase the reliability of soldering in addition to the reduction of the manufacturing cost, thereby improving the yield and the competitiveness in the market.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A chip board package structure, comprising:
a circuit board part including a circuit substrate and a first circuit layer, wherein the first circuit layer is provided on an upper surface of the circuit substrate, and includes a plurality of first circuit patterns and a plurality of first connection pads, and the circuit patterns and first connection pads are connected to each other;
a chip board part including a chip board, a second circuit layer, a third circuit layer and a chip, wherein the second circuit layer is formed on an upper surface of the chip board, and includes a plurality of second circuit patterns, a plurality of wiring pads and a chip base, the second circuit patterns, the wiring pads and the chip base are connected to one another, a surface treatment metal layer is formed on upper surfaces of the second circuit patterns, the wiring pads and the chip base, the chip is attached to the surface treatment metal layer on the chip base through a thermally conductive adhesive, a plurality of electrically conductive wires are connected to the respective wiring pads so as to electrically connect the chip and the second circuit layer, the third circuit layer is formed beneath a lower surface of the chip board and includes a plurality of third circuit patterns and a plurality of third connection pads, the third circuit patterns and the third connection pads are connected to each other, and the second circuit layer and the third circuit layer are electrically connected to each other through at least one connection plug in one hole formed on the chip board; and
a solder formed between the first connection pads and the third connection pads, wherein the first connection pads and the corresponding third connection pads are soldered to each other by the solder, each of the surface treatment metal layer and the electrical conductive wires includes at least nickel, palladium and gold, and a copper-tin intermetallic compound is formed on joints of the solder and the first connection pads and joints of the solder and the third connection pads.

2. The chip board package structure as claimed in claim 1, wherein the circuit board part further includes a first solder mask layer provided on the upper surface of the circuit substrate and covering the first circuit patterns and part of the first connection pads, the chip board part further including a third solder mask provided on the lower surface of the chip board and covering the third circuit patterns and part of the third connection pads.

3. The chip board package structure as claimed in claim 1, wherein the chip board part further includes an encapsulating glue formed on the upper surface of the chip board and covering the second circuit layer, the surface treatment metal layer, the chip, the thermally conductive adhesive and the electrical wires.

4. A chip board package structure, comprising:
a circuit board part including a circuit substrate and a first circuit layer, wherein the first circuit layer is provided on an upper surface of the circuit substrate, and includes a plurality of first circuit patterns and a plurality of first connection pads, and the circuit patterns and first connection pads are connected to each other;
a chip board part including a chip board, a second circuit layer, a third circuit layer and a first chip, wherein the second circuit layer is formed on an upper surface of the chip board, and includes a plurality of second circuit patterns and a plurality of second connection pads, the second circuit patterns and the second connection pads are connected to each other, a surface treatment metal layer is formed on upper surfaces of the second circuit patterns and the second connection pads, each of chip pins of the first chip is soldered to the corresponding second connection pad through a second solder, the third circuit layer is formed on the lower surface of the chip board and includes a plurality of third circuit patterns and a plurality of third connection pads, the third circuit patterns and the third connection pads are connected to each other, the second circuit layer and the third circuit layer are electrically connected to each other through at least one connection plug in one hole formed on the chip board; and
a first solder formed between the first connection pads and the third connection pads, wherein the first connection pads and the corresponding third connection pads are soldered to each other, the surface treatment metal layer includes at least nickel, palladium and gold, a copper-tin intermetallic compound is formed on joints of the second solder and the surface treatment metal layer on the second connection pads, and another copper-tin intermetallic compound is formed on joints of the first solder and the first connection pads and joints of the first solder and the third connection pads.

5. The chip board package structure as claimed in claim 4, wherein the circuit board part further includes a first solder mask layer provided on the upper surface of the circuit substrate and covering the first circuit patterns and part of the first connection pads, the chip board part further includes a second solder mask and a third solder mask, the second solder mask is formed on the lower surface of the chip board and covering the third circuit patterns and part of the second connection pads, and the third solder mask is formed on the lower surface of the chip board and covering the third circuit patterns and part of the third connection pads.

6. The chip board package structure as claimed in claim 5, wherein the chip board part further includes at least one passive element, and each passive element is soldered to the corresponding one of the second connection pads through the second solder.

7. The chip board package structure as claimed in claim 5, wherein the chip board part further includes an encapsulating glue formed on the upper surface of the chip board and covering the second circuit layer, the surface treatment metal layer, the first chip, the second solder mask and the second solder.

8. The chip board package structure as claimed in claim 6, wherein the chip board part further includes an encapsulating glue formed on the upper surface of the chip board and covering the second circuit layer, the surface treatment metal layer, the first chip, the at least one passive element and the second solder.

9. The chip board package structure as claimed in claim 5, wherein the chip board part further includes a second chip, a length of the first chip is less than with a length of second chip and provided beneath the second chip, chip pins of the second chip are provided on an outer rim of the second chip and not in contact with the first chip, the chip pins of the second chip are soldered to the corresponding second connection pads through the second solder.

10. The chip board package as claimed in claim 9, wherein the chip board part further includes an encapsulating glue formed on the upper surface of the chip board and covering the second circuit layer, the surface treatment metal layer, the first chip, the second chip, the second solder mask and the second solder.

11. A chip board package structure, comprising:
a circuit board part including a circuit substrate and a first circuit layer, wherein the first circuit layer is provided on an upper surface of the circuit substrate, and includes a plurality of first circuit patterns and a plurality of first connection pads, and the circuit patterns and first connection pads are connected to each other;
a chip board part including a chip board, a second circuit layer, a third circuit layer, a first chip and at least one passive element, wherein the second circuit layer is formed on an upper surface of the chip board, and includes a plurality of second circuit patterns and a plurality of second connection pads, the second circuit patterns and the second connection pads are connected to each other, the first chip has a plurality of chip pins, each of the second connection pads is soldered to the corresponding chip pin or the corresponding passive element through a second solder, a surface treatment metal layer is formed on the second connection pads which are soldered to the passive element, the third circuit layer is formed on the lower surface of the chip board and includes a plurality of third circuit patterns and a plurality of third connection pads, the third circuit patterns and the third connection pads are connected to each other, and the second circuit layer and the third circuit layer are electrically connected to each other through at least one connection plug in hole formed on the chip board; and
a first solder formed between the first connection pads and the third connection pads, wherein the first connection pads and the corresponding third connection pads are soldered to each other, the surface treatment metal layer includes nickel, palladium and gold, a copper-tin intermetallic compound is formed on joints of the second solder and the surface treatment metal layer on the second connection pads, and another copper-tin intermetallic compound is formed on joints of the first solder and the first connection pads and joints of the first solder and the third connection pads.

12. The chip board package structure as claimed in claim 11, wherein the circuit board further includes a first solder mask formed on the upper surface of the circuit substrate and covering the first circuit patterns and part of the first connection pads, the chip board part further includes a second solder mask and a third solder mask, the second solder mask is formed on the lower surface of the chip board and covering the third circuit patterns and part of the second connection pads, and the third solder mask is formed on the lower surface of the chip board and covering the third circuit patterns and part of the third connection pads.

13. The chip board package structure as claimed in claim 11, wherein the chip board part further includes an encapsulating glue formed on the upper surface of the chip board and covering the second circuit layer, the surface treatment metal layer, the first chip, the second solder mask, the second solder and the at least one passive element.
